(19) United States
(12) Patent Application Publication
(10) Pub. No.: US 2026/0082795 A1
(43) Pub. Date: Mar. 19, 2026

(54) DISPLAY DEVICE

(71) Applicant: Magnolia White Corporation, Tokyo (JP)

(72) Inventors: Ryota TAKASAKI, Tokyo (JP); Hiroshi TABATAKE, Tokyo (JP); Kazuyuki HARADA, Tokyo (JP); Sho YANAGISAWA, Tokyo (JP)

(73) Assignee: Magnolia White Corporation, Tokyo (JP)

(21) Appl. No.: 19/332,102

(22) Filed: Sep. 18, 2025

(30) Foreign Application Priority Data
Sep. 18, 2024 (JP) 2024-161026

(51) Int. Cl. H10K 59/80; H10K 59/122; H10K 59/88

(52) U.S. Cl. CPC H10K 59/871; H10K 59/122; H10K 59/88

(57) ABSTRACT

According to one embodiment, a display device includes a display area including subpixels, a partition including a lower portion and an upper portion, display elements respectively provided in the subpixels and each including an organic layer, and sealing layers covering each of the display elements. The partition includes first and second segments that are divided from each other by a slit extending in a first direction and are arranged in a second direction intersecting the first direction, and a first connecting portion crossing the slit to connect the segments. The sealing layers include a first sealing layer overlapping at least a portion of the first connecting portion in plan view.

### CROSS-REFERENCE TO RELATED APPLICATIONS

This application is based upon and claims the benefit of priority from Japanese Patent Application No. 2024-161026, filed Sep. 18, 2024, the entire contents of which are incorporated herein by reference.

### FIELD

Embodiments described herein relate generally to a display device.

### BACKGROUND

Recently, display devices with organic light-emitting diodes (OLED) applied thereto as display elements have been put into practical use. In this type of display devices, a technique for improving the yield is required.

### BRIEF DESCRIPTION OF THE DRAWINGS

FIG. 1 is a view showing a configuration example of a display device according to the first embodiment.

FIG. 2 is a schematic plan view showing an example of the layout of subpixels.

FIG. 3 is a schematic cross-sectional view of the display device along the III-III line of FIG. 2.

FIG. 4 is a schematic plan view showing some components of the display device according to the first embodiment.

FIG. 5 is a schematic plan view showing a configuration example applicable to a partition and a sealing layer according to the first embodiment.

FIG. 6A is a schematic cross-sectional view of the display device along the A-A line of FIG. 5.

FIG. 6B is a schematic cross-sectional view of the display device along the B-B line of FIG. 5.

FIG. 6C is a schematic cross-sectional view of the display device along the C-C line of FIG. 5.

FIG. 7A is a schematic cross-sectional view showing the first modified example.

FIG. 7B is another schematic cross-sectional view showing the first modified example.

FIG. 8A is a schematic cross-sectional view showing the second modified example.

FIG. 8B is another schematic cross-sectional view showing the second modified example.

FIG. 8C is still another schematic cross-sectional view showing the second modified example.

FIG. 9 is a flowchart showing an example of a manufacturing method of the display device according to the first embodiment.

FIG. 10A is a schematic cross-sectional view showing a manufacturing process of the display device.

FIG. 10B is a schematic cross-sectional view showing a process following the one shown in FIG. 10A.

FIG. 10C is a schematic cross-sectional view showing a process following the one shown in FIG. 10B.

FIG. 10D is a schematic cross-sectional view showing a process following the one shown in FIG. 10C.

FIG. 10E is a schematic cross-sectional view showing a process following the one shown in FIG. 10D.

FIG. 10F is a schematic cross-sectional view showing a process following the one shown in FIG. 10E.

FIG. 10G is a schematic cross-sectional view showing a process following the one shown in FIG. 10F.

FIG. 11 is a schematic cross-sectional view showing the configuration for a comparative example.

FIG. 12 is a schematic cross-sectional view for describing effects of the first embodiment.

FIG. 13 is a schematic plan view of a partition and sealing layers according to the second embodiment.

FIG. 14 is a schematic cross-sectional view of the display device along the A-A line of FIG. 13.

FIG. 15 is a schematic cross-sectional view showing a modified example of the second embodiment.

FIG. 16 is a schematic plan view of a partition and sealing layers according to the third embodiment.

FIG. 17 is a schematic cross-sectional view of the display device along the A-A line of FIG. 16.

FIG. 18 is a schematic cross-sectional view showing a modified example of the third embodiment.

FIG. 19 is a schematic plan view of a partition and sealing layers according to the fourth embodiment.

FIG. 20 is a schematic cross-sectional view of the display device along the A-A line of FIG. 19.

FIG. 21 is a schematic cross-sectional view showing a modified example of the fourth embodiment.

FIG. 22 is a schematic plan view of a display device according to the fifth embodiment.

FIG. 23 is a schematic plan view showing a configuration example applicable to a dummy pixel area.

FIG. 24A is a schematic cross-sectional view of the display device along the A-A line of FIG. 23.

FIG. 24B is a schematic cross-sectional view of the display device along the B-B line of FIG. 23.

FIG. 24C is a schematic cross-sectional view of the display device along the C-C line of FIG. 23.

### DETAILED DESCRIPTION

In general, according to one embodiment, According to an embodiment, a display device includes a display area including a plurality of subpixels, a partition surrounding each of the plurality of subpixels and including a lower portion having conductivity and an upper portion having an end portion protruding relative to a side surface of the lower portion, a plurality of display elements respectively provided in the plurality of subpixels and each including an organic layer that emits light in response to application of a voltage, and a plurality of sealing layers formed of an inorganic insulating material and covering each of the plurality of display elements. The partition includes a first segment and a second segment that are divided from each other by a slit extending in a first direction and are arranged in a second direction intersecting the first direction, and a first connecting portion crossing the slit to connect the first segment with the second segment. The plurality of sealing layers include a first sealing layer overlapping at least a portion of the first connecting portion in plan view.

This configuration can improve the yield of the display device.

Embodiments will be described hereinafter with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes and the like, of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis, and a Z-axis orthogonal to each other are described to facilitate understanding as needed. A direction parallel to the X-axis is referred to as an X-direction. A direction parallel to the Y-axis is referred to as a Y-direction. A direction parallel to the Z-axis is referred to as a Z-direction. The Z-direction is the normal direction of a plane including the X-direction and the Y-direction. When various elements are viewed parallel to the Z-direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

### First Embodiment

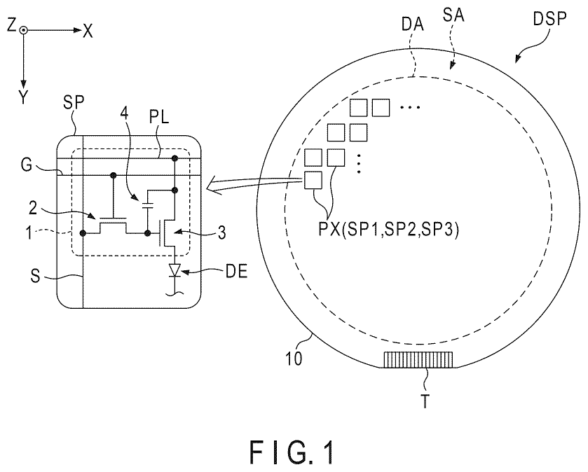

FIG. 1 is a view showing a configuration example of a display device DSP according to the first embodiment. The display device DSP comprises an insulating substrate 10. The substrate 10 has a display area DA for displaying images and a surrounding area SA around the display area DA. The substrate 10 may be glass or a resinous film having flexibility.

In the present embodiment, the substrate 10 and the display area DA have a circular shape in plan view. The shape of each of the substrate 10 and the display area DA in plan view is not limited to a circular shape and may be another shape such as a rectangular shape, a square shape, or an elliptic shape.

The display area DA comprises a plurality of pixels PX arranged in a matrix in the X-direction and the Y-direction. Each pixel PX includes a plurality of subpixels SP that display different colors. The present embodiment assumes a case where each pixel PX includes a blue subpixel SP1, a green subpixel SP2, and a red subpixel SP3. Each pixel PX may include a subpixel SP that exhibits another color such as white in addition to the subpixels SP1, SP2, and SP3 or instead of one of the subpixels SP1, SP2, and SP3.

The display device DSP further comprises a terminal portion T provided in the surrounding area SA. For example, a flexible printed circuit board, which applies voltage and signals for driving the display device DSP is connected to the terminal portion T.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

The display area DA has a plurality of scanning lines G supplying the pixel circuit 1 of each subpixel SP with scanning signals, a plurality of signal lines S supplying the pixel circuit 1 of each subpixel SP with video signals, and a plurality of power lines PL. In the example of FIG. 1, the scanning lines G and the power lines PL extend in the X-direction, and the signal lines S extend in the Y-direction. However, the configuration is not limited to this example.

The gate electrode of the pixel switch 2 is connected to the scanning line G. One of a source electrode and the drain electrode of the pixel switch 2 is connected to the signal line S. The other is connected to a gate electrode of the drive transistor 3 and the capacitor 4. In the drive transistor 3, one of the source electrode and a drain electrode is connected to the power line PL and the capacitor 4. The other is connected to a display element DE.

The configuration of the pixel circuit 1 is not limited to the example of the figure. For example, the pixel circuit 1 may comprise more thin-film transistors and more capacitors.

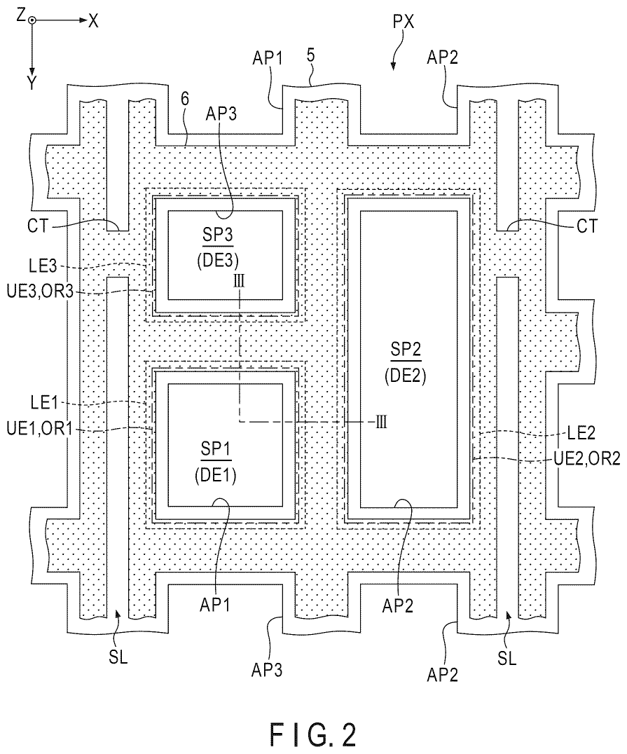

FIG. 2 is a schematic plan view showing an example of the layout of the subpixels SP1, SP2, and SP3 constituting one pixel PX. In the example of FIG. 2, the subpixels SP1 and SP3 are arranged in the Y-direction. Each of the subpixels SP1 and SP3 is arranged with the subpixel SP2 in the X-direction.

When the subpixels SP1, SP2, and SP3 are arranged in this layout, in the display area DA, a column in which the subpixels SP1 and SP3 are alternately arranged in the Y-direction and a column in which the plurality of subpixels SP2 are repeatedly arranged in the Y-direction are formed. These columns are alternately arranged in the X-direction. The layout of the subpixels SP1, SP2, and SP3 is not limited to the example of FIG. 2.

A rib layer 5 is provided in the display area DA. The rib layer 5 has pixel apertures AP1, AP2 and AP3 in the respective subpixels SP1, SP2 and SP3. In the example of FIG. 2, each of the pixel apertures AP1, AP2, and AP3 has a rectangular shape. The planar size of each of the pixel apertures AP1 and AP2 is greater than that of the pixel aperture AP3. The pixel aperture AP2 is elongated in the Y-direction more than the pixel apertures AP1 and AP3. The shapes of the pixel aperture AP1, AP2, and AP3 are not limited to this example.

The subpixel SP1 comprises a lower electrode LE1, an upper electrode UE1, and an organic layer OR1, which overlap the pixel aperture AP1. The subpixel SP2 comprises a lower electrode LE2, an upper electrode UE2, and an organic layer OR2, which overlap the pixel aperture AP2. The subpixel SP3 comprises a lower electrode LE3, an upper electrode UE3, and an organic layer OR3, which overlap the pixel aperture AP3.

The lower electrode LE1, the upper electrode UE1, and the organic layer OR1 constitute a display element DE1 of the subpixel SP1. The lower electrode LE2, the upper electrode UE2, and the organic layer OR2 constitute a display element DE2 of the subpixel SP2. The lower electrode LE3, the upper electrode UE3, and the organic layer OR3 constitute a display element DE3 of the subpixel SP3. Each of the display elements DE1, DE2, and DE3 may further include a cap layer to be described later. The rib layer 5 surrounds each of the display elements DE1, DE2, and DE3.

A conductive partition 6 is provided above the rib layer 5. The partition 6 functions as lines which divide the display elements DE1, DE2, and DE3 from each other and supply the upper electrodes UE1, UE2, and UE3 with common voltage. The partition 6 entirely overlaps the rib layer 5 and has the same planar shape as that of the rib layer 5. The partition 6 surrounds the subpixels SP1, SP2, and SP3.

The partition 6 has a plurality of slits SL extending in the Y-direction (the first direction). The slits SL do not overlap the lower electrodes LE1, LE2, and LE3. In the example of FIG. 2, the subpixels SP1, SP2, and SP3 constituting one pixel PX are provided between two slits SL in the X-direction (the second direction). Further, the partition 6 has a connecting portion CT, which connects portions divided by the slit SL (segments to be described later) to each other. The layout of the slits SL and the connecting portion CT is not limited to the example of FIG. 2.

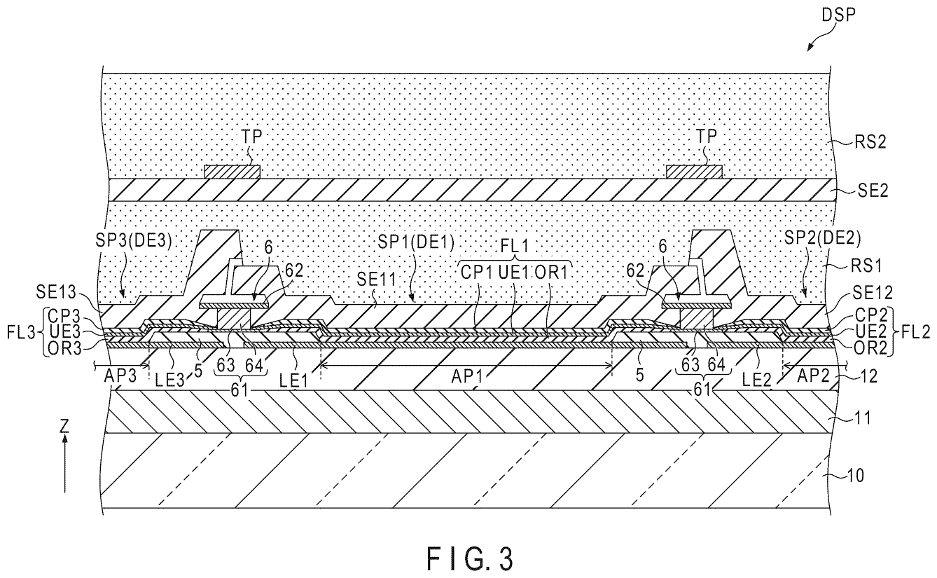

FIG. 3 is a schematic cross-sectional view of the display device DSP along the III-III line of FIG. 2. A circuit layer 11 is provided on the substrate 10 described above. The circuit layer 11 includes various circuits and lines such as the pixel circuit 1, scanning line G, signal line S, and power line PL shown in FIG. 1. The circuit layer 11 is covered with an organic insulating layer 12. The organic insulating layer 12 functions as a planarization film which planarizes irregularities formed by the circuit layer 11.

Each of the lower electrodes LE1, LE2, and LE3 is provided on the organic insulating layer 12. The rib layer 5 is provided on the organic insulating layer 12 and the lower electrodes LE1, LE2, and LE3. End portions of the lower electrodes LE1, LE2, and LE3 are all covered with the rib layer 5.

The partition 6 includes a conductive lower portion 61 provided on the rib layer 5 and an upper portion 62 provided on the lower portion 61. The upper portion 62 has a width greater than that of the lower portion 61. This configuration allows both end portions of the upper portion 62 to protrude relative to the side surfaces of the lower portion 61. That is, the partition 6 has an overhang shape in which the both end portions of the upper portion 62 protrude relative to the side surfaces of the lower portion 61.

In the example of FIG. 3, the lower portion 61 includes a bottom layer 63 and a stem layer 64. The bottom layer 63 is formed to be thinner than the stem layer 64 and is located between the stem layer 64 and the rib layer 5. The both end portions of the bottom layer 63 protrude relative to the respective side surfaces of the stem layer 64.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 contact the lower portions 61 of the partition 6.

The display element DE1 includes a cap layer CP1 covering the upper electrode UE1. The display element DE2 includes a cap layer CP2 covering the upper electrode UE2. The display element DE3 includes a cap layer CP3 covering the upper electrode UE3. The cap layers CP1, CP2, and CP3 function as optical adjustment layers which improve the extraction efficiency of the light emitted from the respective organic layers OR1, OR2, and OR3.

In the following explanation, a multilayer body including the organic layer OR1, the upper electrode UE1, and the cap layer CP1 is called a stacked film FL1. A multilayer body including the organic layer OR2, the upper electrode UE2, and the cap layer CP2 is called a stacked film FL2. A multilayer body including the organic layer OR3, the upper electrode UE3, and the cap layer CP3 is called a stacked film FL3.

Sealing layers SE11, SE12, and SE13, which cover the respective stacked films FL1, FL2, and FL3 are provided in the respective subpixels SP1, SP2, and SP3. More specifically, the sealing layer SE11 continuously covers the cap layer CP1 and the partition 6 around the subpixel SP1. The sealing layer SE12 continuously covers the cap layer CP2 and the partition 6 around the subpixel SP2. The sealing layer SE13 continuously covers the cap layer CP3 and the partition 6 around the subpixel SP3.

In the example of FIG. 3, the sealing layers SE11 and SE12 overlap in the Z-direction above the partition 6 between the subpixels SP1 and SP2. Further, the sealing layers SE11 and SE13 overlap in the Z-direction above the partition 6 between the subpixels SP1 and SP3. The configuration is not limited to this example. The sealing layers SE11, SE12, and SE13 may be spaced apart from each other above the partition 6.

For example, gaps are formed between the respective sealing layers SE11, SE12, and SE13 and the upper portion 62 of the partition 6. The stacked films FL1, FL2, and FL3 may be provided in at least part of these gaps.

The sealing layers SE11, SE12, and SE13 are covered with a resin layer RS1. The resin layer RS1 is covered with the sealing layer SE2. The sealing layer SE2 is covered with a resin layer RS2. The resin layers RS1 and RS2 and the sealing layer SE2 are continuously provided in at least the entire display area DA and partly extend in the surrounding area SA as well.

In the example of FIG. 3, a touch panel electrode TP for detecting touch operations by a user is provided on the sealing layer SE2. For example, the touch panel electrode TP is formed of a metal material and has the same shape as that of the partition 6 in plan view.

A cover member such as a polarizer, a protective film, and a cover glass may be further provided above the resin layer RS2. This cover member may be attached to the resin layer RS2 via, for example, an adhesive layer such as an optical clear adhesive (OCA).

The organic insulating layer 12 is formed of an organic insulating material such as a polyimide.

Each of the rib layer 5 and the sealing layers SE11, SE12, SE13, and SE2 is formed of an inorganic insulating material such as a silicon nitride (SiNx), a silicon oxide (SiOx), or a silicon oxynitride (SiON).

In one example, the rib layer 5 is formed of a silicon oxynitride, and each of the sealing layers SE11, SE12, SE13, and SE2 is formed of a silicon nitride. Each of the resin layers RS1 and RS2 is formed of, for example, a resinous material (organic insulating materials) such as an epoxy resin or an acrylic resin.

Each of the lower electrodes LE1, LE2, and LE3 has a reflective layer formed of, for example, silver, and a pair of conductive oxide layers covering the upper and lower surfaces of the reflective layer. Each of the conductive oxide layers can be formed of, for example, a transparent conductive oxide such as an indium tin oxide (ITO), an indium zinc oxide (IZO), or an indium gallium zinc oxide (IGZO).

The upper electrodes UE1, UE2, and UE3 are formed of, for example, a metal material such as an alloy of magnesium and silver (MgAg). For example, the lower electrodes LE1, LE2, and LE3 correspond to anodes, and the upper electrodes UE1, UE2, and UE3 correspond to cathodes.

Each of the organic layers OR1, OR2, and OR3 is formed of a plurality of thin films including a light emitting layer. As an example, the organic layers OR1, OR2, and OR3 have a structure in which a hole-injection layer, a hole-transport layer, an electron blocking layer, a light emitting layer, a hole blocking layer, an electron-transport layer, and an electron-injection layer are stacked in this order in the Z-direction. The organic layers OR1, OR2, and OR3 each may comprise other structures such as a tandem structure including a plurality of light emitting layers.

Each of the cap layers CP1, CP2, and CP3 comprises, for example, a multilayer structure in which a plurality of transparent layers are stacked. These transparent layers may include a layer formed of an inorganic material and a layer formed of an organic material. The transparent layers have refractive indices different from each other. For example, the refractive indices of these transparent layers are different from the refractive indices of the upper electrodes UE1, UE2, and UE3 and the refractive indices of the sealing layers SE11, SE12, and SE13. At least one of the cap layers CP1, CP2, and CP3 may be omitted.

For example, each of the bottom layer 63 and the stem layer 64 of the partition 6 is formed of a metal material. For the metal material of the bottom layer 63, for example, molybdenum, titanium, titanium nitride (TiN), a molybdenum-tungsten alloy (MoW), or a molybdenum-niobium alloy (MoNb) can be used. For the metal material of the stem layer 64, for example, aluminum, an aluminum-neodymium alloy (AlNd), an aluminum-yttrium alloy (AlY), or an aluminum-silicon alloy (AlSi) can be used. The stem layer 64 may be formed of an insulating material.

For example, the upper portion 62 of the partition 6 includes a lower layer formed of a metal material and an upper layer formed of a conductive oxide. In this case, titanium, titanium nitride, molybdenum, tungsten, a molybdenum-tungsten alloy, or a molybdenum-niobium alloy can be used for the metal material forming the lower layer. Further, an ITO or an IZO may be used for a conductive oxide forming the upper layer. The upper portion 62 may comprise three or more layers or may consist of a single layer. The upper portion 62 may further include a layer formed of an insulating material.

The partition 6 is supplied with common voltage. This common voltage is applied to each of the upper electrodes UE1, UE2, and UE3 in contact with the lower portions 61. The lower electrodes LE1, LE2, and LE3 are supplied with pixel voltages according to the video signals of the signal lines S through the respective pixel circuits 1 provided in the subpixels SP1, SP2, and SP3.

The organic layers OR1, OR2, and OR3 emit light in response to the application of a voltage. Specifically, when a potential difference is formed between the lower electrode LE1 and the upper electrode UE1, the light emitting layer of the organic layer OR1 emits light in a blue wavelength range. When a potential difference is formed between the lower electrode LE2 and the upper electrode UE2, the light emitting layer of the organic layer OR2 emits light in a green wavelength range. When a potential difference is formed between the lower electrode LE3 and the upper electrode UE3, the light emitting layer of the organic layer OR3 emits light in a red wavelength range.

As another example, the light emitting layers of the organic layers OR1, OR2, and OR3 may emit light beams of the same color (for example, white). In this case, the display device DSP may comprise a color filter that converts the light emitted from the light emitting layers into light beams of the colors corresponding to those of the subpixels SP1, SP2, and SP3. In addition, the display device DSP may comprise a layer including quantum dots that are excited by the light emitted from the light emitting layers to generate the light of the colors corresponding to those of the subpixels SP1, SP2, and SP3.

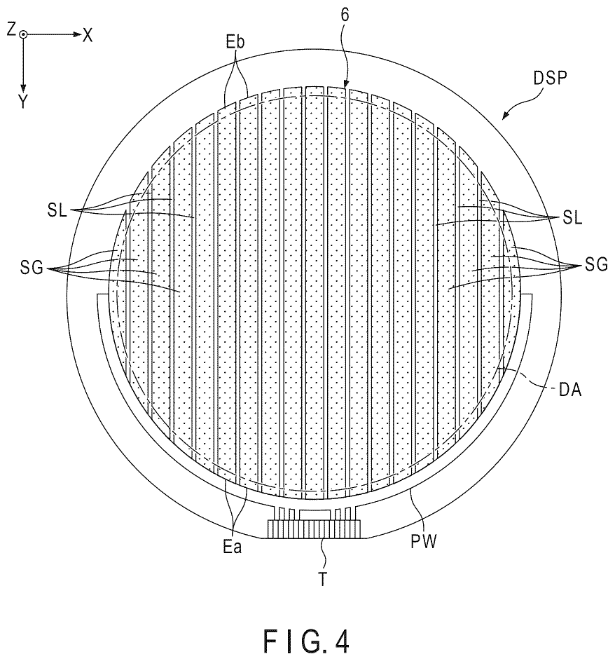

FIG. 4 is a schematic plan view showing some elements of the display device DSP. The partition 6 is divided into a plurality of segments SG by a plurality of slits SL shown in FIG. 2 as well. FIG. 4 schematically shows the slits SL and the segments SG. For example, when the slits SL are located on both sides of the pixel PX in the X-direction as shown in FIG. 2, more slits SL are formed in the display area DA.

At least some of the plurality of segments SG are connected to each other by the connecting portions CT, which cross the slit SL as shown in FIG. 2. On the other hand, the connecting portions CT may not be provided in some of the plurality of slits SL.

Each of the segments SG has a first end portion Ea and a second end portion Eb in the extension direction of the slits SL (the Y-direction in the present embodiment). The first end portion Ea is connected to a power supply line PW provided in the surrounding area SA. The power supply line PW is connected to the terminal portion T. Each of the segments SG is supplied with common voltage from the terminal portion T via the power supply line PW. In the example of FIG. 4, the second end portions Eb of the segments SG are spaced apart from each other by the slits SL. That is, these second end portions Eb are not connected to each other by a conductive member such as the power supply line PW.

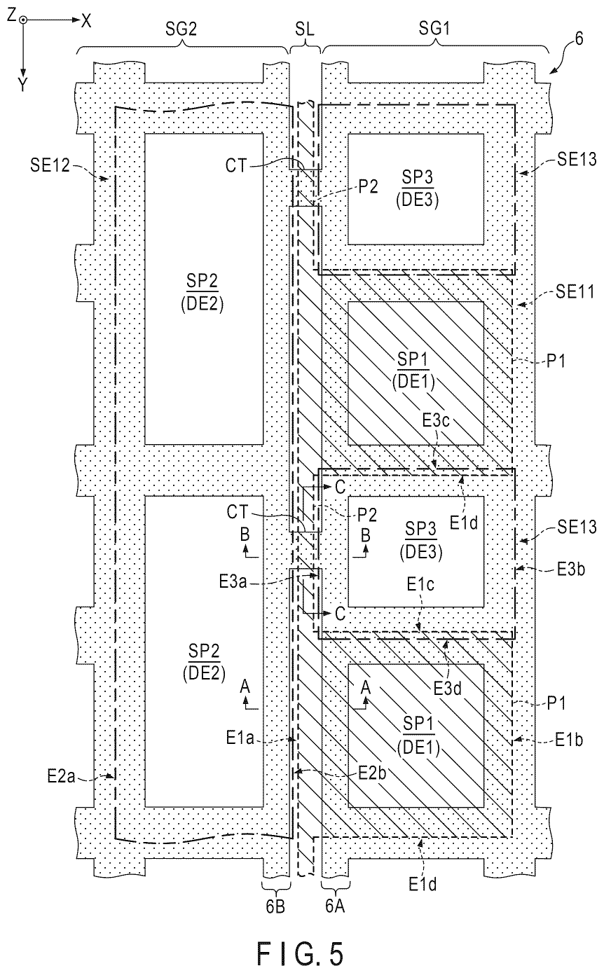

FIG. 5 is a schematic plan view showing a configuration example applicable to the partition 6 and the sealing layers SE11, SE12, and SE13 according to the present embodiment. This figure partially shows two segments SG1 and SG2 divided by the slit SL (the first and second segments). Further, the sealing layer SE11 is indicated by the hatch-line pattern. In the following description, the portion that is adjacent to the slit SL and extends in the Y-direction of the segment SG1 is referred to as a partition 6A, and the portion that is adjacent to the slit SL and extends in the Y-direction of the segment SG2 is referred to as a partition 6B.

The segments SG1 and SG2 are connected to each other by a plurality of connecting portions CT. In the example of FIG. 5, the connecting portion CT is provided at a position arranged with the subpixel SP3 (the display element DE3) in the X-direction. The position of the connecting portion CT is not limited to this example.

The sealing layer SE11 has a plurality of first portions P1 overlapping the subpixel SP1 (the display element DE1) and a plurality of second portions P2 overlapping at least a portion of the slit SL. For example, the sealing layer SE12 is formed continuously over the plurality of subpixels SP2 (the display elements DE2) arranged in the Y-direction.

The first portion P1 and the sealing layer SE12 are arranged in the X-direction via the slit SL. The sealing layers SE12 and SE13 are arranged in the X-direction via the slit SL as well. The first portion P1 and the sealing layer SE13 are arranged in the Y-direction without the interposition of the slit SL.

The second portion P2 of the sealing layer SE11 extends in the Y-direction with passing through between the sealing layers SE12 and SE13. Each of both end portions in the Y-direction of the second portion P2 is connected to the first portion P1. The second portion P2 overlaps at least a portion of the connecting portion CT.

The first portion P1 has end portions E1a and E1b in the X-direction and end portions E1c and E1d in the Y-direction. The sealing layer SE12 has end portions E2a and E2b in the X-direction. The sealing layer SE13 has end portions E3a and E3b in the X-direction and end portions E3c and E3d in the Y-direction. For example, the end portions E1a, E1b, E2a, E2b, E3a, and E3b have straight-line shapes parallel to the Y-direction. The end portions E1c, E1d, E3c, and E3d have straight-line shapes parallel to the X-direction.

In the example of FIG. 5, the end portions E1c and E3d overlap. Further, the end portions E1d and E3c overlap. The configuration is not limited to this example. The end portions E1c and E3d may be spaced apart from each other. Similarly, the end portions E1d and E3c may be spaced apart from each other.

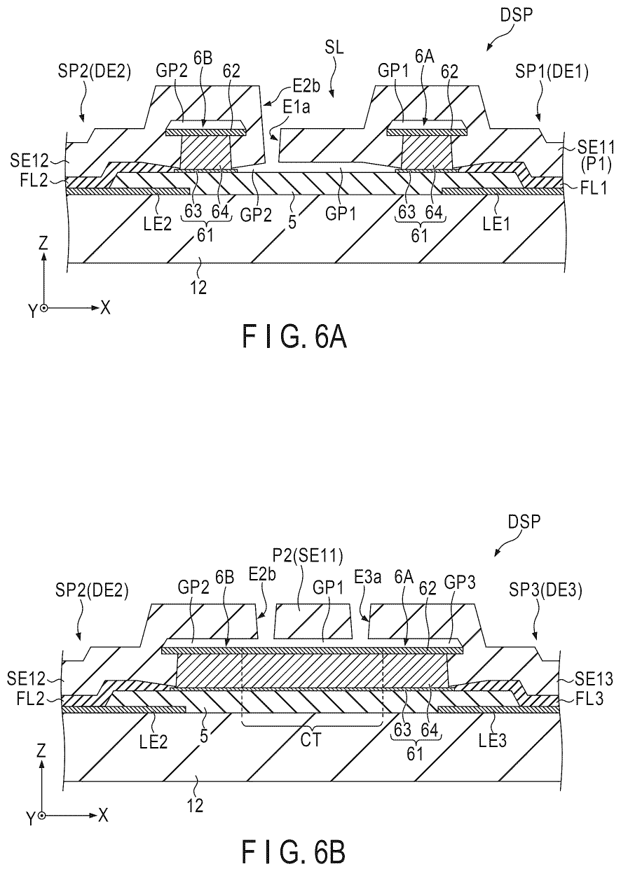

FIG. 6A is a schematic cross-sectional view of the display device DSP along the A-A line of FIG. 5. The partitions 6A and 6B divided by the slit SL have an overhang shape in the same manner as the partitions 6 shown in FIG. 3. In the slit SL, the rib layer 5 has no apertures. That is, the slit SL entirely overlaps the rib layer 5.

In the cross section of FIG. 6A, the first portion P1 of the sealing layer SE11 covers the partition 6A. The end portion E1a of the first portion P1 is located in the slit SL. The sealing layer SE12 covers the partition 6B. For example, the end portion E2b of the sealing layer SE12 is located in the slit SL and faces the end portion E1a via a gap. In another example, the end portion E2b may be located above the partition 6B.

FIG. 6B is a schematic cross-sectional view of the display device DSP along the B-B line of FIG. 5. In the same manner as each of the partitions 6A and 6B, the connecting portion CT includes the lower portion 61 (the bottom layer 63 and the stem layer 64) and the upper portion 62. The bottom layer 63, the stem layer 64, and the upper portion 62 of the connecting portion CT are connected to the bottom layers 63, the stem layers 64, and the upper portions 62 of the partitions 6A and 6B.

The second portion P2 of the sealing layer SE11 is located above the connecting portion CT. The end portion E2b of the sealing layer SE12 faces the second portion P2 via a gap. Similarly, the end portion E3a of the sealing layer SE13 faces the second portion P2 via a gap.

FIG. 6C is a schematic cross-sectional view of the display device DSP along the C-C line of FIG. 5. The cross-sectional shape of the connecting portion CT along the Y-direction has the same overhang shape as those of the partitions 6A and 6B. The second portion P2 of the sealing layer SE11 extends along the slit SL and crosses the connecting portion CT.

In the examples shown in FIG. 6A to FIG. 6C, except for the portions that overlap the display elements DE1, DE2, and DE3, a gap GP1 is formed below the sealing layer SE11, a gap GP2 is formed below the sealing layer SE12, and a gap GP3 is formed below the sealing layer SE13. More specifically, the respective gaps GP1 are formed between the upper portion 62 of partition 6A and the first portion P1, between the rib layer 5 and the first portion P1 in the slit SL, between the upper portion 62 of the connecting portion CT and the second portion P2, and between the rib layer 5 and the second portion P2 in the slit SL. Further, the respective gaps GP2 are formed between the upper portion 62 of the partition 6B and the sealing layer SE12 and between the rib layer 5 and the sealing layer SE12 in the slit SL. The gap GP3 is formed between the upper portion 62 of the partition 6A and the sealing layer SE13.

The gaps GP1, GP2, and GP3 correspond to the spaces where the stacked films FL1, FL2, and FL3, which were temporarily formed during the manufacturing process of the display device DSP, have been removed by various etching processes. These gaps GP1, GP2, and GP3 may be hollow or may be filled at least partially with the resin layer RS1 (refer to FIG. 3).

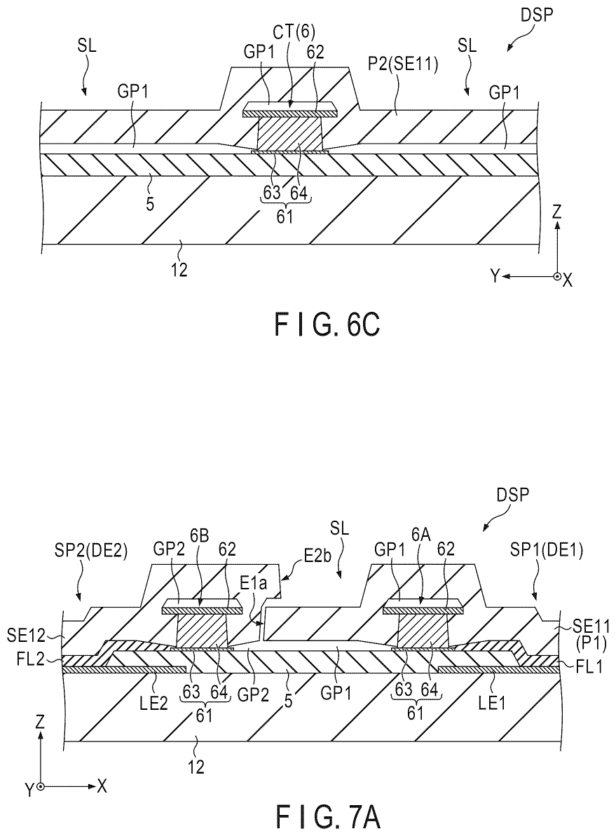

FIGS. 7A and 7B are schematic cross-sectional views of the first modified example of the present embodiment. FIG. 7A corresponds to a cross section along the A-A line of FIG. 5. FIG. 7B corresponds to a cross section along the B-B line of FIG. 5.

The configuration of FIG. 7A differs from that of FIG. 6A in that the end portion E2b of the sealing layer SE12 overlaps the end portion E1a of the first portion P1. The end portion E2b is located above the end portion E1a in the Z-direction.

The configuration of FIG. 7B differs from that of FIG. 6B in that each of the end portion E2b of the sealing layer SE12 and the end portion E3a of the sealing layer SE13 overlaps the second portion P2. Each of the end portions E2b and E3a is located above the second portion P2 in the Z-direction.

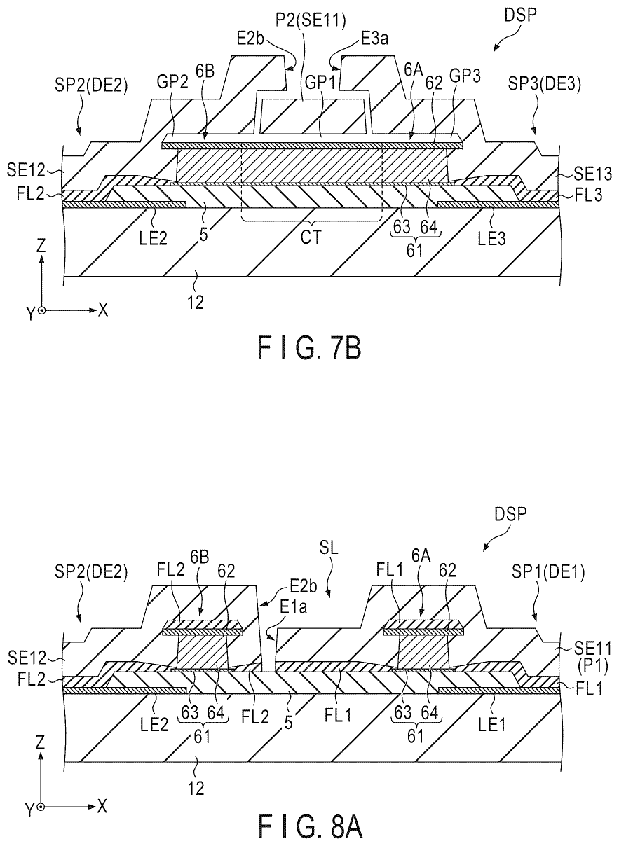

FIG. 8A to FIG. 8C are schematic cross-sectional views of the second modified example of the present embodiment. FIG. 8A corresponds to a cross section along the A-A line of FIG. 5. FIG. 8B corresponds to a cross section along the B-B line of FIG. 5. FIG. 8C corresponds to a cross section along the C-C line of FIG. 5.

In FIG. 8A to FIG. 8C, the stacked films FL1, FL2, and FL3 are provided at locations corresponding to the respective gaps GP1, GP2, and GP3 in FIG. 6A to FIG. 6C. The stacked films FL1, FL2, and FL3 may be provided to partially fill the locations corresponding to the gaps GP1, GP2, and GP3 in FIG. 6A to FIG. 6C. In the configuration of the first modified example shown in FIG. 7A and FIG. 7B, the respective stacked films FL1, FL2, and FL3 may be provided at the locations corresponding to the gaps GP1, GP2, and GP3.

The following describes an example of the manufacturing method of the display device DSP.

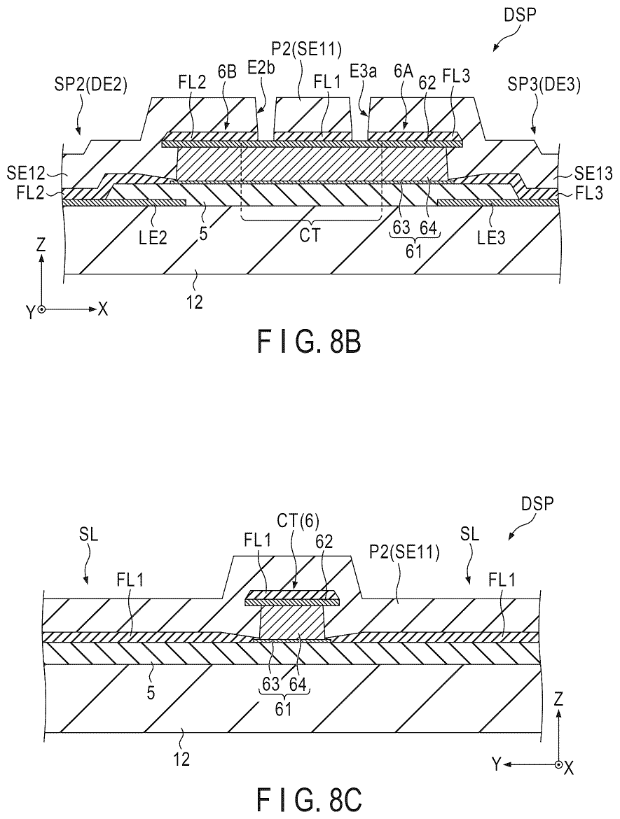

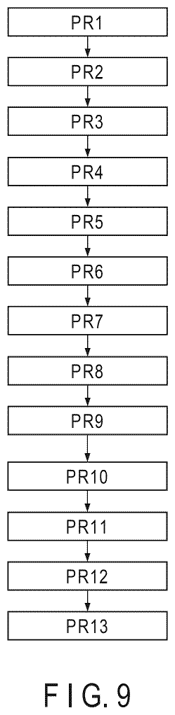

FIG. 9 is a flowchart showing an example of the manufacturing method of the display device DSP. FIG. 10A to FIG. 10G are schematic cross-sectional views showing the manufacturing processes of the display device DSP. FIG. 10A to FIG. 10G mainly focus on the display area DA and omit the elements below the organic insulating layer 12.

In the manufacturing of the display device DSP, first, the circuit layer 11 is formed on the substrate 10 (the process PR1 in FIG. 9). Further, the organic insulating layer 12 covering the circuit layer 11 is formed (the process PR2 in FIG. 9).

After the process PR2, as shown in FIG. 10A, the lower electrodes LE1, LE2, and LE3 are formed on the organic insulating layer 12 (the process PR3 in FIG. 9). Further, the rib layer 5 covering the lower electrodes LE1, LE2, and LE3 is formed (the process PR4 in FIG. 9). At this time, the pixel apertures AP1, AP2, and AP3 are not provided in the rib layer 5. The rib layer 5 may be formed by chemical vapor deposition (CVD).

After the formation of the rib layer 5, the partition 6 is formed on the rib layer 5 as shown in FIG. 10B (the process PR5 in FIG. 9). For example, in the formation of the partition 6, material layers of the bottom layer 63, the stem layer 64, and the upper portion 62 are formed over an entire mother substrate MB. Further, a resist having the shape corresponding to the partition 6 is provided on these layers.

Etching each layer using this resist as a mask can form the partition 6, which is open in each of the subpixels SP1, SP2, and SP3 and includes the plurality of segments SG divided by the slit SL.

Next, as shown in FIG. 10C, the pixel apertures AP1, AP2, and AP3 are formed in the rib layer 5 (the process PR6 in FIG. 9). The pixel apertures AP1, AP2, and AP3 may be formed prior to the formation of the partition 6.

After the process PR6, a process for forming the display element DE1 is performed (the process PR7 in FIG. 9). In the formation of the display element DE1, the stacked film FL1 and the sealing layer SE11 are formed first on the entire substrate as shown in FIG. 10D. As shown in FIG. 3, the stacked film FL1 includes the organic layer OR1 contacting the lower electrode LE1 through the pixel aperture AP1, the upper electrode UE1 covering the organic layer OR1, and the cap layer CP1 covering the upper electrode UE1.

For example, the organic layer OR1, the upper electrode UE1, and the cap layer CP1 may be formed by vapor deposition. For example, the sealing layer SE11 may be formed by CVD. The stacked film FL1 is divided by the partition 6 having an overhang shape. The sealing layer SE11 continuously covers these portions, into which the stacked film FL1 has been divided, and the partition 6.

Subsequently, the stacked film FL1 and the sealing layer SE11 are patterned. In this patterning, as shown in FIG. 10D, a resist RT1 is provided on the sealing layer SE11. The resist RT1 covers the subpixel SP1 and part of the partition 6 around the subpixel SP1.

Subsequently, an etching process using the resist RT1 as a mask is performed. This process removes the portions that are exposed from the resist RT1 of the stacked film FL1 and the sealing layer SE11 as shown in FIG. 10E. This process forms the display element DE1 in the subpixel SP1.

This etching process may include wet etching and dry etching performed in order for the sealing layer SE11, the cap layer CP1, the upper electrode UE1, and the organic layer OR1. After these etching processes, the resist RT1 is removed (stripped).

In the etching processes, the stacked film FL1 in the vicinity of the end portion of the sealing layer SE11 may be removed to from the gap GP1. The gap GP1 may be formed by various etching processes performed after these etching processes. Further, the stacked film FL1 may remain in at least a portion of the gap GP1.

After the process PR7, a process for forming the display element DE2 is performed (the process PR8 in FIG. 9). The display element DE2 can be formed by the same procedure as that of the display element DE1. That is, in the formation of the display element DE2, the stacked film FL2 and the sealing layer SE12 are formed in the entire substrate. The stacked film FL2 includes the organic layer OR2 contacting the lower electrode LE2 through the pixel aperture AP2, the upper electrode UE2 covering the organic layer OR2, and the cap layer CP2 covering the upper electrode UE2, as shown in FIG. 3.

The organic layer OR2, the upper electrode UE2, and the cap layer CP2 may be formed by, for example, vapor deposition. The sealing layer SE12 may be formed by, for example, CVD. Patterning these stacked film FL2 and sealing layer SE2 forms the display element DE2 in the subpixel SP2 as shown in FIG. 10F.

In the example of FIG. 10F, the stacked film FL2 in the vicinity of the end portion of the sealing layer SE12 is removed to form the gap GP2. The gap GP2 may be formed by various etching processes performed after these etching processes. Further, the stacked film FL2 may remain in at least a portion of the gap GP2.

After the process PR8, a process for forming the display element DE3 is performed (the process PR9 in FIG. 9). The display element DE3 can be formed by the same procedures as those of the display elements DE1 and DE2. That is, in the formation of the display element DE3, the stacked film FL3 and the sealing layer SE13 are formed in the entire substrate. The stacked film FL3 includes the organic layer OR3 contacting the lower electrode LE3 through the pixel aperture AP3, the upper electrode UE3 covering the organic layer OR3, and the cap layer CP3 covering the upper electrode UE3, as shown in FIG. 3.

The organic layer OR3, the upper electrode UE3, and the cap layer CP3 may be formed by, for example, vapor deposition. The sealing layer SE13 may be formed by, for example, CVD. Patterning these stacked film FL3 and sealing layer SE13 forms the display element DE3 in the subpixel SP3, as shown in FIG. 10G.

In the example of FIG. 10G, the stacked film FL3 in the vicinity of the end portion of the sealing layer SE13 is removed to form the gap GP3. Further, the stacked film FL3 may remain in at least a portion of the gap GP3.

Here, the above description assumes that the display elements DE1, DE2, and DE3 are formed in this order. However, the display elements DE1, DE2, and DE3 may be formed in another order.

After the process PR9, the resin layer RS1 is formed, for example, by the ink-jet method (the process PR10 in FIG. 9). Further, the sealing layer SE2 is formed by, for example, CVD (the process PR11 in FIG. 9).

After the process PR11, the touch panel electrode TP is formed on the sealing layer SE2 (the process PR12 in FIG. 9). Thereafter, the resin layer RS2 covering the touch panel electrodes TP and the sealing layer SE2 is formed, for example, by an ink-jet method (the process PR13 in FIG. 9). The display device DSP is completed by the manufacturing method including at least these processes.

The following describes several effects exhibited by the display device DSP according to the present embodiment.

Electronic devices on which the display device DSP is mounted may comprise an optical sensor such as an illumination sensor, which detects external light. When the optical sensor is provided on the rear side of the display device DSP, the display device DSP needs to have a light transmitting property.

However, each of the lower electrodes LE1, LE2, and LE3 includes the reflective layer. In addition, the partition 6, that is at least partly formed of a metal material, has a light-shielding property. Thus, in configurations where the lower electrodes LE1, LE2, and LE3 and the partition 6 are provided without gaps in the display area DA, most of the light incident on the display surface of the display device DSP may be reflected or blocked without being transmitted to the rear surface of the display device DSP.

To the contrary, in configurations where the slits SL are provided in the partition 6 as in the present embodiment, part of the light incident on the display surface is transmitted to the rear surface of the display device DSP through the slits SL. This configuration can enhance the light transmitting property of the display device DSP.

An electronic device on which the display device DSP is mounted may comprise an antenna for near field communication (NFC). This antenna is provided to face the rear surface of the display device DSP and wirelessly communicates with another electronic device through the display device DSP. A magnetic field formed by the antenna generates an eddy current in the partition 6 at the time of wireless communications. These eddy currents form a magnetic field in the direction opposite to the above magnetic field, thereby attenuating the signal strength of the wireless communication. Thus, wireless communication performed via the display device DSP could result in a decrease in the communication sensitivity.

The eddy currents may be attenuated by dividing the partition 6. That is, as described above in the explanation on FIG. 4, providing the slit SL in which no connecting portion CT is provided suppresses the generation of large eddy currents in the partition 6, thereby suppressing a decrease in communication sensitivity.

Thus, the present embodiment can provide a display device DSP compatible with an optical sensor and an antenna for wireless communication. Further, as described below, the present embodiment described above can improve the yield of the display device DSP.

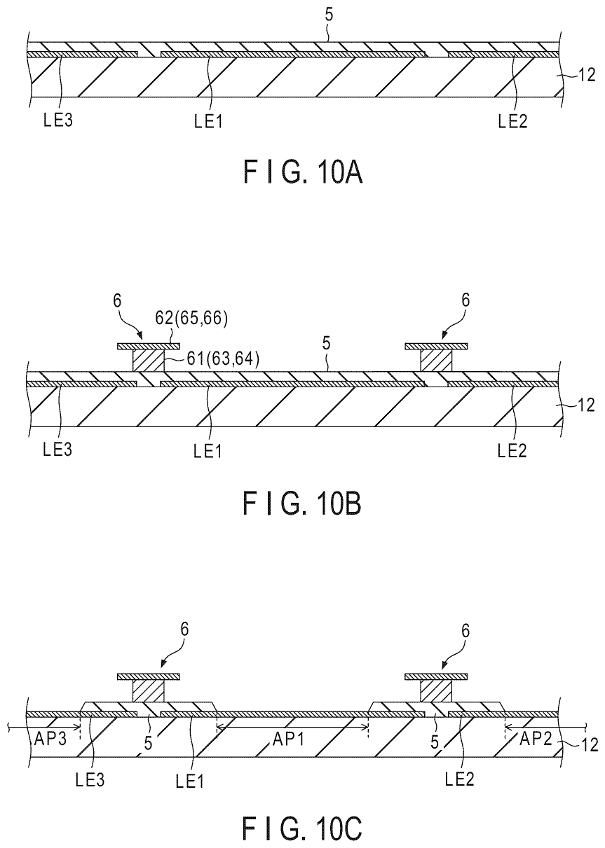

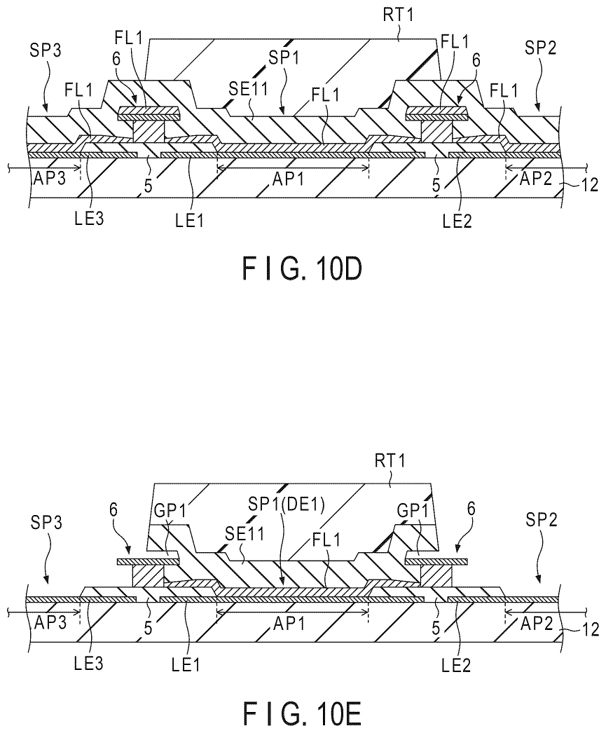

FIG. 11 is a schematic cross-sectional view of the configuration of a comparative example for the present embodiment. FIG. 12 is a schematic cross-sectional view for describing effects of the present embodiment. The cross-sections in these figures show the states immediately after the stacked film FL2 and the sealing layer SE12, and the resist RT2 for patterning them have been formed at the same locations as those in FIG. 6A. At the time shown in FIG. 11, the resist RT2 has not been processed into a shape corresponding to the final planar shape of the sealing layer SE12 and is formed over the entire display area DA.

In the comparative example show in FIG. 11, the end portion E1a of the sealing layer SE11 is located above the partition 6A. That is, the sealing layer SE11 does not overlap the slit SL. In this configuration, a large step ST caused by the partition 6A and the end portion E1a may be formed on the sealing layer SE12 and the resist RT2. At locations such as the step ST where the shape of the resist RT2 changes drastically, air bubbles may be introduced into the resist RT2. These air bubbles introduced into the resist RT2 may burst during the vacuum drying of the resist RT2 and may make the sealing layer SE12, which should be covered by the resist RT2, exposed.

In contrast, in the present embodiment, as shown in FIG. 12, the end portion E1a of the sealing layer SE11 (the first portion P1) is located in the slit SL. In this case, the large step ST as shown in the comparative example shown in FIG. 11 is not likely to be formed in the sealing layer SE12 and the resist RT2. Thus, the configuration of the present embodiment can suppress introductions of air bubbles into the resist RT2.

The step ST shown in FIG. 11 may also be formed in the sealing layer SE13 and the resist for processing the sealing layer SE13 due to the sealing layer SE12. In contrast, in the present embodiment, the second portion P2 of the sealing layer SE11 is provided between the sealing layers SE12 and SE13 as shown in FIG. 5. This also suppresses introductions of air bubbles into the resist for processing the sealing layer SE13.

A corner portion of the sealing layer SE11 formed of an inorganic insulating material is particularly prone to cracking. If the sealing layer SE11 does not have the second portion P2, that is, if the sealing layer SE11 has a rectangular shape constituted by the first portion P1 alone, the base shape of the sealing layer SE11 becomes unstable when its corners overlap the partition 6 and the slit SL. Therefore, the cracks may occur more readily. Such cracks also contribute to introductions of air bubbles into the resist provided on the sealing layer SE11.

With respect to this point, the second portion P2 is connected to the corner of the first portion P1 in the present embodiment. This configuration can suppress the occurrence of cracks at the corner portions.

When the resin layer RS1 is formed by the ink-jet method, most of the uncured resin droplets ejected from the nozzle first adhere to the sealing layers SE11, SE12, and SE13 and then spread over the area where the resin layer RS1 is to be formed. If the sealing layers SE11, SE12, and SE13 are not provided in the slit SL, the droplets may not spread to the slit SL due to the surface tension at the end portions of the sealing layers SE11, SE12, and SE13. This may result in a shape defect of the resin layer RS1.

In contrast, the configuration in which the slit SL is filled by the second portion P2 as in the present embodiment allows the droplets to spread suitably even above the slit SL. This configuration can suppress a shape defect of the resin layer RS1.

In addition to the above effects, the present embodiment can achieve various desirable effects.

### Second Embodiment

The following describes the second embodiment. Configurations that are not particularly referred to may adopt the same configurations as those of the first embodiment.

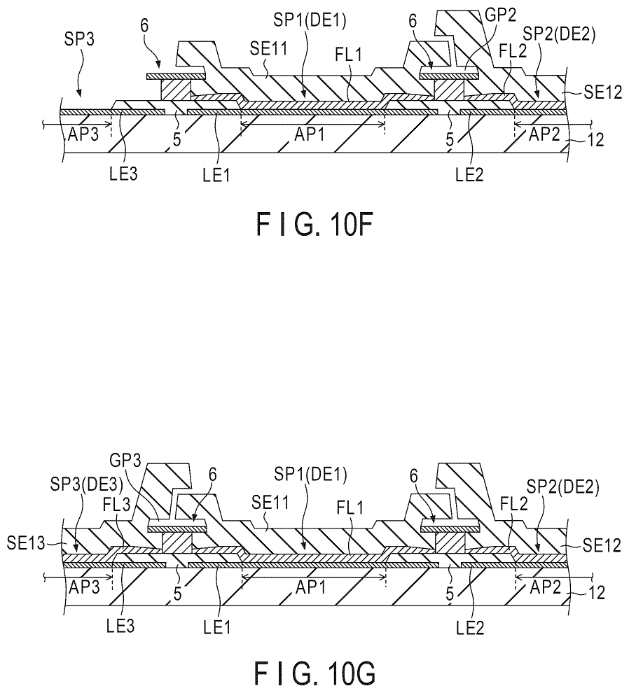

FIG. 13 is a schematic plan view of the partition 6 and the sealing layers SE11, SE12, and SE13 according to the present embodiment. The present embodiment differs from the first embodiment in the shape of the sealing layer SE11 and the layout of the connecting portion CT.

That is, in the example of FIG. 13, the sealing layer SE11 does not have the second portion P2 shown in FIG. 5 and has a shape corresponding to the first portion P1. In addition, the connecting portion CT is provided at positions arranged in the X-direction with the partition 6 between the subpixels SP1 and SP3.

The sealing layer SE11 has the end portions E1a, E1b, E1c, and E1d that the first portion P1 in the first embodiment has. The end portions E1c and E1d overlap the respective connecting portions CT (the first connecting portion and the second connecting portion, respectively). The end portion E1a is located closer to the sealing layer SE12 than the end portion E3a of the sealing layer SE13.

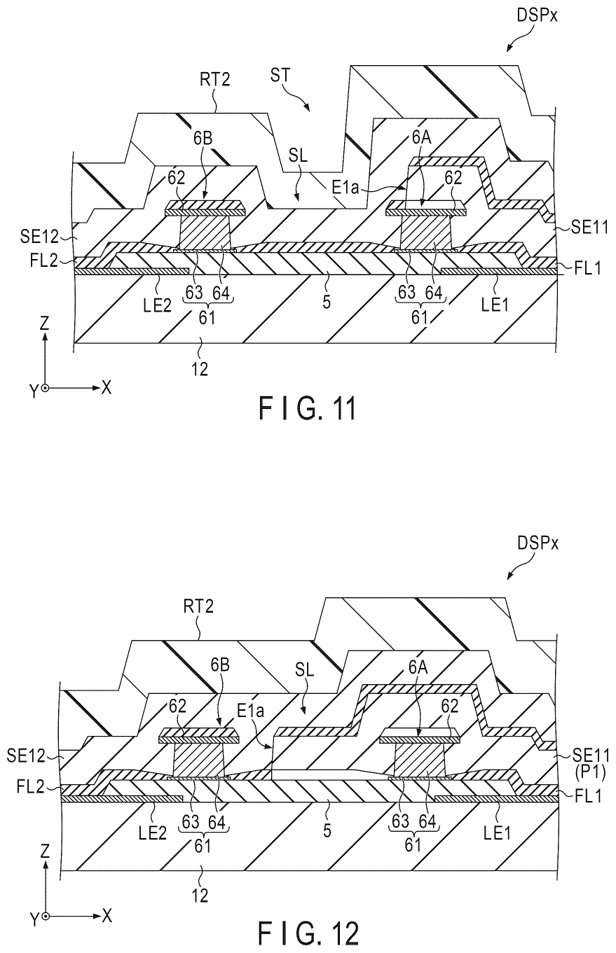

FIG. 14 is a schematic cross-sectional view of the display device DSP along the A-A line of FIG. 13. The end portion E1c of the sealing layer SE11 is located above the connecting portion CT. In the example of FIG. 14, the gaps GP1 are formed between the sealing layer SE11 and the rib layer 5, and between the sealing layer SE11 and the upper portion 62 of the connecting portion CT.

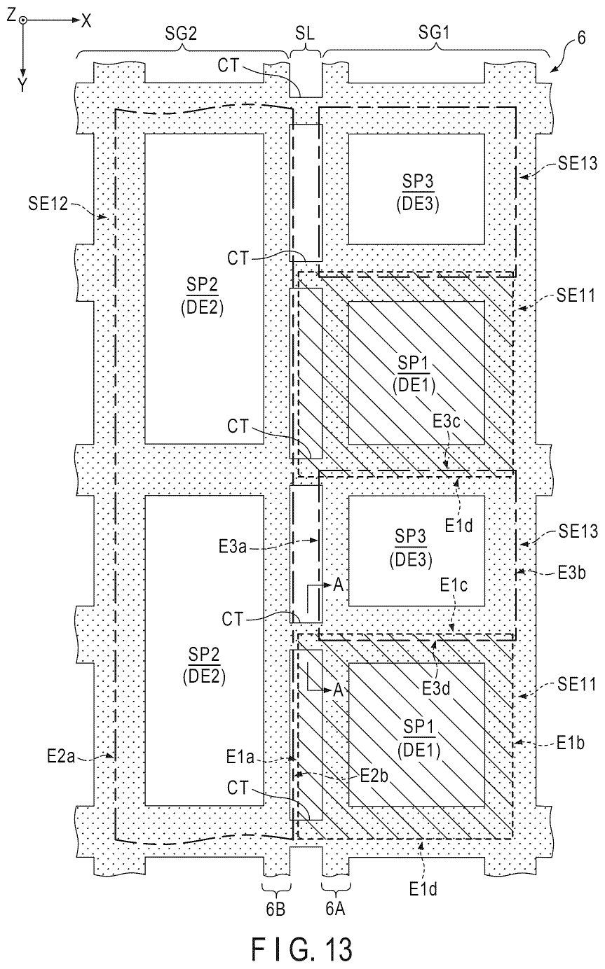

FIG. 15 is a schematic cross-sectional view showing a modified example of the present embodiment. In this modified example, the stacked films FL1 are provided in the location corresponding to the gap GP1 shown in FIG. 14. The stacked films FL1 may be provided to fill portions of the locations corresponding to the gaps GP1 in FIG. 14.

In the same manner as the first embodiment, the configuration of the present embodiment can reduce the step ST shown in the comparative example of FIG. 11, thereby suppressing introductions of air bubbles into the resist. Further, in the present embodiment, the corner portions of the sealing layer SE11 constituted by the end portions E1a, E1c, and E1d are all located on the connecting portion CT. This configuration stabilizes the base shape of these corner portions and suppresses the occurrence of cracks in the sealing layer SE11.

Furthermore, in the present embodiment, the area that overlap the second portion P2 of the slit SL in the first embodiment does not overlap any of the sealing layers SE11, SE12, and SE13. This increases the transmittance of the areas.

### Third Embodiment

The following describes the third embodiment. Configurations that are not particularly referred to may adopt the same configurations as those of the above embodiments.

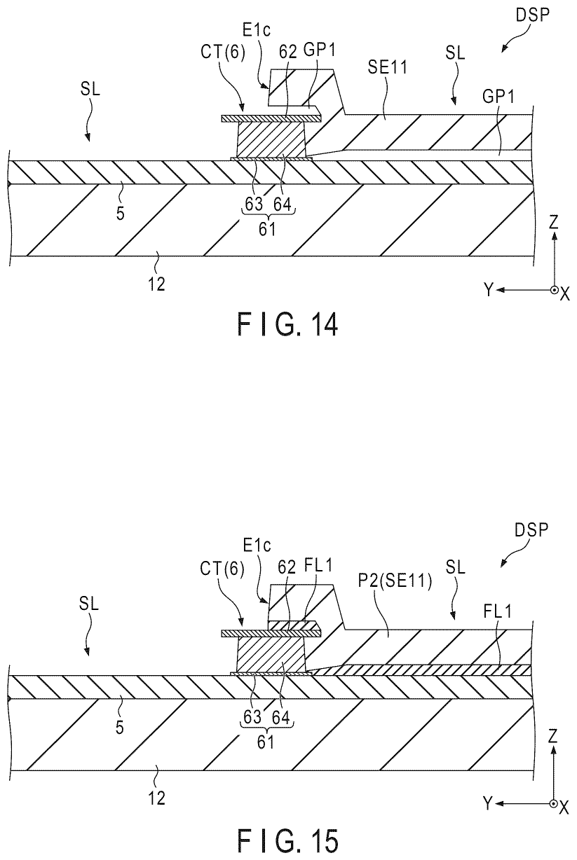

FIG. 16 is a schematic plan view of the partition 6 and the sealing layers SE11, SE12, and SE13 according to the present embodiment. The present embodiment differs from the second embodiment in the shape of the sealing layer SE11.

That is, in the example of FIG. 16, the end portions E1c and E1d of the sealing layer SE11 overlap the slit SL. As a result, the most part of the connecting portion CT in the vicinity of the end portions E1c and E1d is covered with the sealing layer SE11.

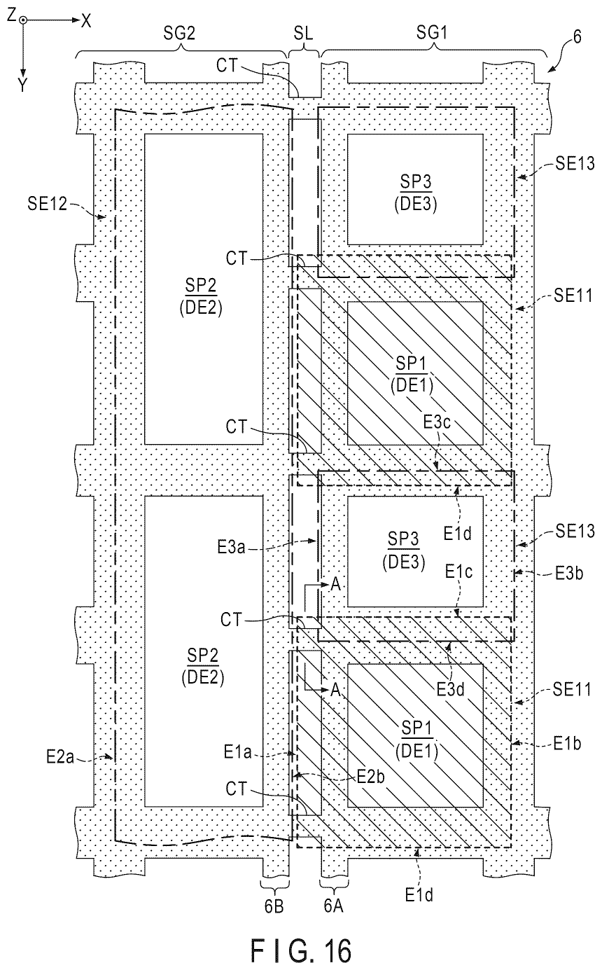

FIG. 17 is a schematic cross-sectional view of the display device DSP along the A-A line of FIG. 16. The end portion E1c of the sealing layer SE11 is located above the rib layer 5 in the slit SL. The connecting portion CT is entirely covered with the sealing layer SE11. In the example of FIG. 17, the gaps GP1 are formed between the sealing layer SE11 and the rib layer 5, and between the sealing layer SE11 and the upper portion 62 of the connecting portion CT.

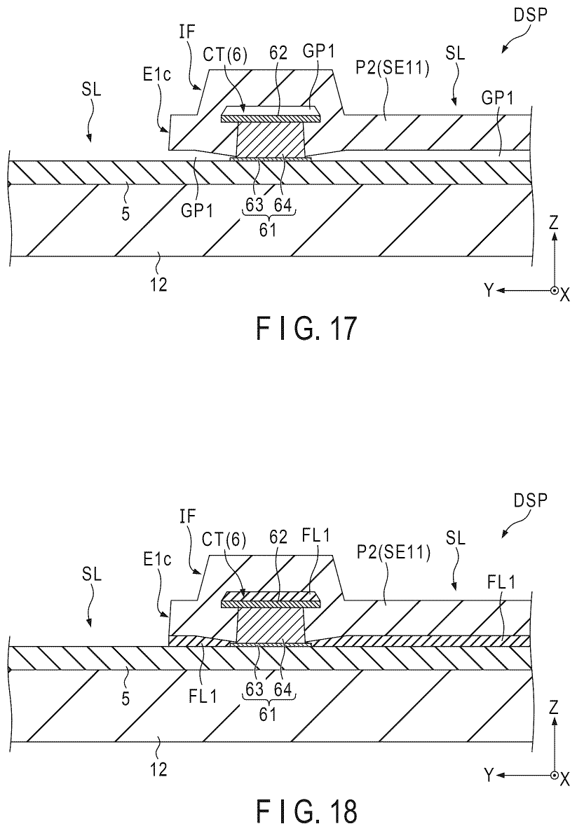

FIG. 18 is a schematic cross-sectional view showing a modified example of the present embodiment. In this modified example, the stacked films FL1 are provided in the locations corresponding to the gaps GP1 shown in FIG. 14. The stacked films FL1 may be provided to fill portions of the locations corresponding to the gaps GP1 in FIG. 17.

The configurations of the present embodiment can exhibit the same effect as those of each embodiment. In the configuration shown in FIG. 14 of the second embodiment, when the resin layer RS1 is formed by the ink-jet method described above, droplets having adhered to the sealing layer SE11 may not readily spread into the slit SL due to the surface tension of the end portion E1c. In contrast, in the configurations shown in FIG. 17 and FIG. 18, an inclined surface IF is formed on the upper surface of the sealing layer SE11 in the vicinity of the end portion E1c. The liquid droplets having adhered to the sealing layer SE11 flow down this inclined surface IF and readily flow beyond the end portion E1c into the slit SL. Thus, the shape defect of the resin layer RS1 can be suitably suppressed.

### Fourth Embodiment

The following describes the fourth embodiment. Configurations that are not particularly referred to may adopt the same configurations as those of the above embodiments.

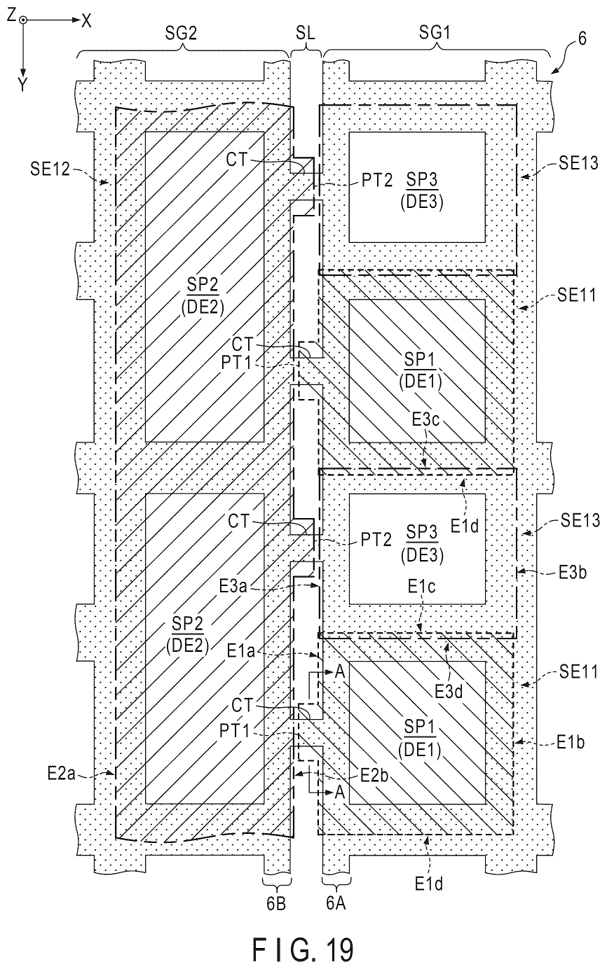

FIG. 19 is a schematic plan view of the partition 6 and the sealing layers SE11, SE12, and SE13 according to the present embodiment. The present embodiment differs from the above embodiments in the shape of each of the sealing layers SE11 and SE12 and the layout of the connecting portion CT. FIG. 19 indicates the sealing layers SE11 and SE12 by hatch patterns.

In the example of FIG. 19, the connecting portions CT are provided at positions arranged with the respective subpixels SP1 and SP3 in the X-direction. Further, the sealing layer SE11 has a protrusion portion PT1 (the first protrusion portion), and the sealing layer SE12 has a protrusion portion PT2 (the second protrusion portion).

The protrusion portion PT1 protrudes relative to the end portion E1a of the sealing layer SE11 in the direction parallel to the X-direction (the direction toward the sealing layer SE12). The protrusion portion PT2 protrudes relative to the end portion E2b of the sealing layer SE12 in the direction parallel to the X-direction (the direction toward the sealing layer SE13). In the example of FIG. 19, the distal end of the protrusion portion PT1 is slightly spaced apart from the sealing layer SE12. Further, the distal end of the protrusion portion PT2 is slightly spaced apart from the sealing layer SE13. In another example, the distal end of the protrusion portion PT1 may overlap the sealing layer SE12. Similarly, the distal end of the protrusion portion PT2 may overlap the sealing layer SE13.

The protrusion portion PT1 overlaps at least a portion of the connecting portion CT (the first connecting portion) arranged with the subpixel SP1 in the X-direction. The protrusion portion PT2 overlaps at least a portion of the connecting portion CT (the second connecting portion) arranged with the subpixel SP3 in the X-direction.

In the example of FIG. 19, the width in the Y-direction of the protrusion portion PT1 is greater than the width in the Y-direction of the connecting portion CT overlapping the protrusion portion PT1. This allows a portion of the protrusion portion PT1 to overlap the slit SL in the vicinity of the connecting portion CT. More specifically, the end portions in the Y-direction of the protrusion portion PT1 overlap the slit SL.

In the example of FIG. 19, the width in the Y-direction of the protrusion portion PT2 is greater than the width in the Y-direction of the connecting portion CT overlapping the protrusion portion PT2. This allows a portion of the protrusion portion PT2 to overlap the slit SL in the vicinity of the connecting portion CT as well. More specifically, both end portions in the Y-direction of the protrusion portion PT2 overlap the slit SL.

The protrusion portions PT1 and PT2 are spaced apart from each other in the Y-direction. The most part of the area between the protrusion portions PT1 and PT2 of the slit SL does not overlap the sealing layers SE11, SE12, and SE13.

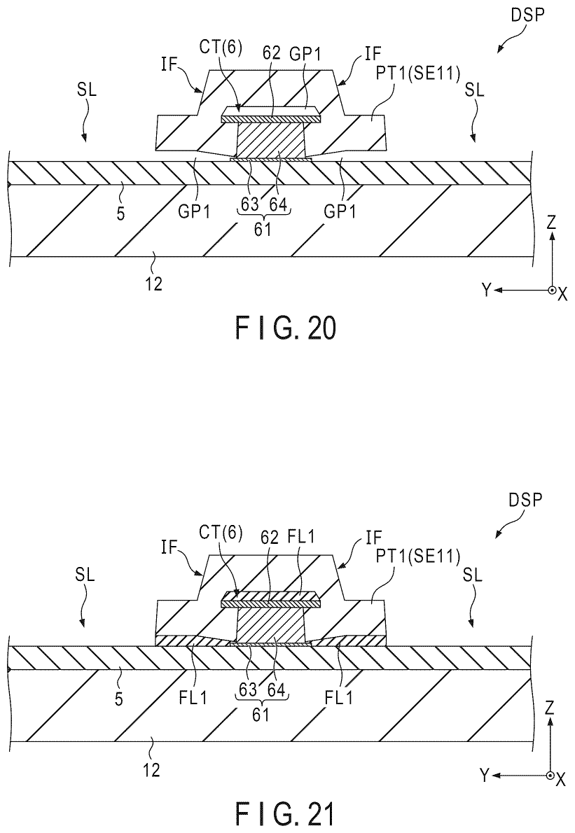

FIG. 20 is a schematic cross-sectional view of the display device DSP along the A-A line of FIG. 19. In addition to the upper portion 62 of the connecting portion CT, the protrusion portion PT1 covers both side portions having an overhang shape of the connecting portion CT. In the example of FIG. 20, the gaps GP1 are formed between the sealing layer SE11 and the rib layer 5, and between the sealing layer SE11 and the upper portion 62.

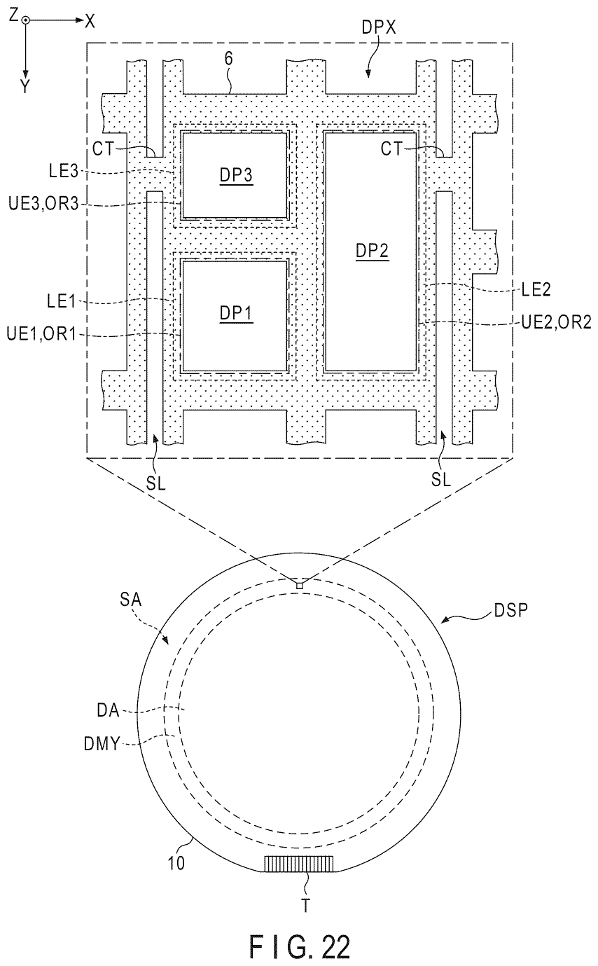

FIG. 21 is a schematic cross-sectional view showing a modified example of the present embodiment. In this modified example, the stacked films FL1 are provided in the locations corresponding to the gaps GP1 shown in FIG. 20. The stacked films FL1 may be provided to fill portions of the locations corresponding to the gaps GP1 in FIG. 20.

The configuration in the vicinity of the protrusion portion PT2 is the same as the configuration in the vicinity of the protrusion portion PT1 shown in FIG. 20 or FIG. 21. That is, the protrusion portion PT2 covers both side portions having an overhang shape of the connecting portion CT. Further, under the protrusion portion PT2, a gap may be formed or the stacked film FL2 may be provided.

The configurations of the present embodiment can exhibit the same effect as those of each embodiment. Further, in the configurations shown in FIG. 20 and FIG. 21, the inclined surfaces IF are formed on the upper surface of the sealing layer SE11 in the vicinity of the both end portions in the Y-direction of the protrusion portion PT1. Thus, the droplets having adhered to the sealing layer SE11 in the formation of the resin layer RS1 readily flow into the slit SL. Furthermore, the configuration in which the area between the protrusion portions PT1 and PT2 of the slit SL does not overlap any of the sealing layers SE11, SE12, and SE13 can increase the transmittance of the area.

### Fifth Embodiment

The following describes the fifth embodiment. Configurations that are not particularly referred to may adopt the same configurations as those of the above embodiments.

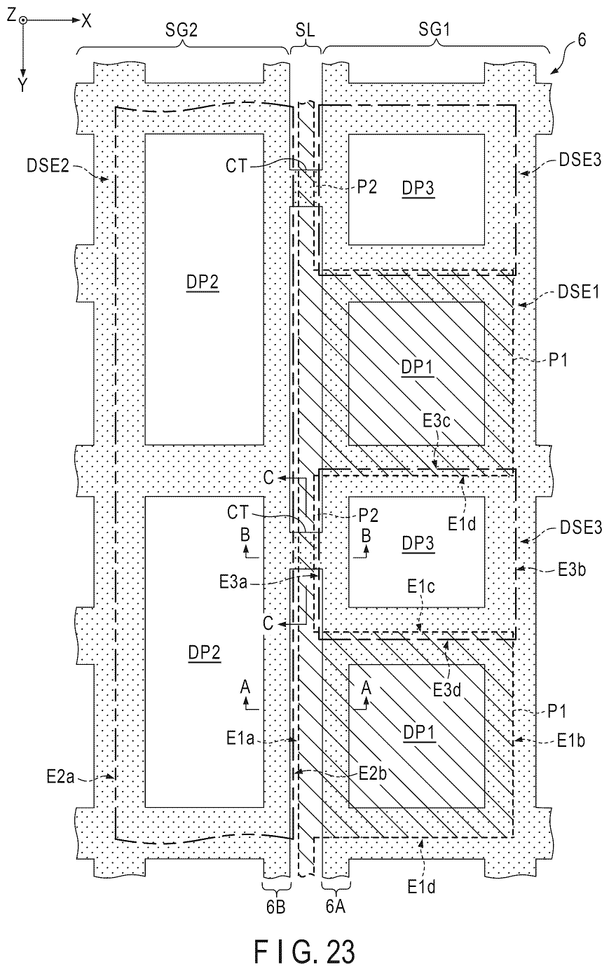

FIG. 22 is a schematic plan view of the display device DSP of the present embodiment. As in the one shown in FIG. 1, the display device DSP includes the insulating substrate 10, the display area DA for displaying images, and the surrounding area SA around the display area DA. Further, the surrounding area SA includes a dummy pixel area DMY surrounding the display area DA.

FIG. 22 shows a portion of the dummy pixel area DMY in an enlarged manner. A plurality of dummy pixels DPX are provided in the dummy pixel area DMY. For example, each dummy pixel DPX includes dummy subpixels DP1, DP2, and DP3. Each of the dummy subpixels DP1, DP2, and DP3 has the configuration similar to that of the respective subpixels SP1, SP2, and SP3 provided in the display area DA.

That is, the dummy subpixel DP1 comprises the lower electrode LE1, the organic layer OR1, and the upper electrode UE1. Further, the dummy subpixel DP2 comprises the lower electrode LE2, the organic layer OR2, and the upper electrode UE2. Further, the dummy subpixel DP3 comprises the lower electrode LE3, the organic layer OR3, and the upper electrode UE3.

However, the dummy subpixels DP1, DP2, and DP3 are configured not to emit light. This configuration may be implemented by, for example, disconnecting a portion of the pixel circuit 1 in each of the dummy subpixels DP1, DP2, and DP3. The pixel apertures AP1, AP2, and AP3 may be omitted in the respective dummy subpixels DP1, DP2, and DP3. Thus, the rib layer 5 is interposed between the organic layers OR1, OR2, and OR3 and the lower electrodes LE1, LE2, and LE3. Thus, currents for making the organic layers OR1, OR2, and OR3 to emit light do not flow through these organic layers OR.

A portion of the partition 6 is located in the dummy pixel area DMY and surrounds each of the plurality of dummy pixels DPX. More specifically, the partition 6 surrounds each of dummy subpixels DP1, DP2 and DP3. The shapes and layout of the apertures of the partition 6 in the respective dummy subpixels DP1, DP2, and DP3 are the same as those of the apertures of the partition 6 in the respective subpixels SP1, SP2, and SP3.

A portion of the slit SL disclosed in each embodiment is located in the dummy pixel area DMY. Further, the connecting portion CT (the third connecting portion) is provided in the dummy pixel area DMY as well.

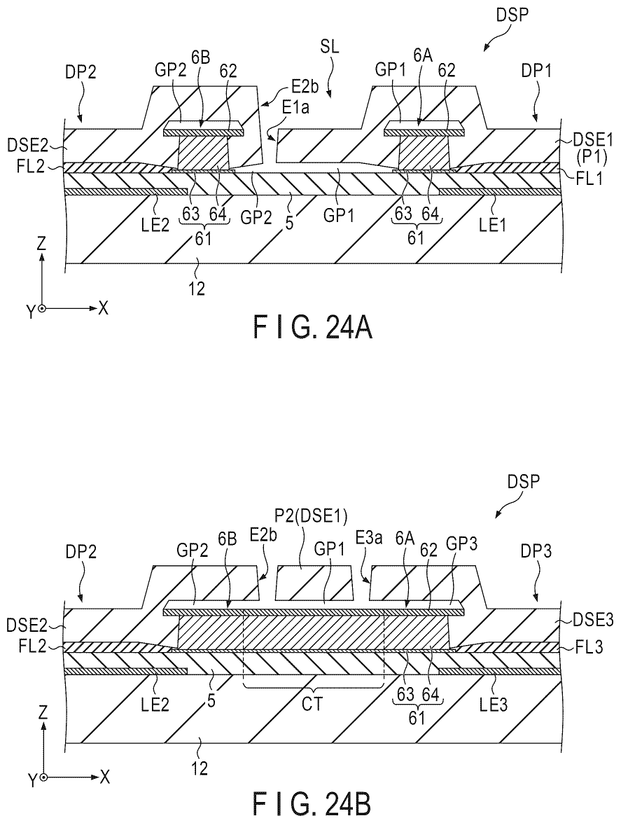

FIG. 23 is a schematic plan view showing a specific configuration example applicable to the dummy pixel area DMY. In the dummy pixel area DMY, a dummy sealing layer DSE1 overlapping the dummy subpixel DP1, a dummy sealing layer DSE2 overlapping the dummy subpixel DP2, and a dummy sealing layer DSE3 overlapping the dummy subpixel DP3 are provided. FIG. 23 indicates the dummy sealing layer DSE1 by a hatch pattern. The dummy sealing layers DSE1, DSE2, and DSE3 are formed of the same inorganic insulating material as those of the sealing layers SE11, SE12, and SE13.

The partition 6 and the dummy sealing layers DSE1, DSE2, and DSE3 in the dummy pixel area DMY can adopt the same configuration as those of the partition 6 and the sealing layers SE11, SE12, and SE13 shown in FIG. 5, FIG. 13, FIG. 16, and FIG. 19. In one example, FIG. 23 shows a case where the partition 6 and the dummy sealing layers DSE1, DSE2, and DSE3 have the same configurations as the partition 6 and the sealing layers SE11, SE12, and SE13 shown in FIG. 5.

That is, as shown in FIG. 23, some of the segments SG1 and SG2 divided by the slit SL are located in the dummy pixel area DMY. The dummy sealing layer DSE1 has a plurality of first portions P1 each overlapping the dummy subpixel DP1 and a plurality of second portions P2 each overlapping at least a portion of the slit SL and a portion of the connecting portion CT. For example, the dummy sealing layer DSE2 is continuously formed across the plurality of dummy subpixels DP2 arranged in the Y-direction. The dummy sealing layer DSE3 is in a rectangular shape and is located between two first portions P1. The first portion P1 has end portions E1a and E1b in the X-direction and end portions E1c and E1d in the Y-direction. The dummy sealing layer DSE2 has the end portions E2a and E2b in the X-direction. The dummy sealing layer DSE3 has the end portions E3a and E3b in the X-direction and the end portions E3c and E3d in the Y-direction.

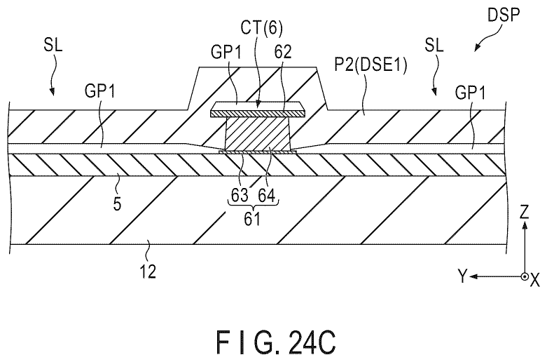

FIG. 24A is a schematic cross-sectional view of the display device DSP along the A-A line of FIG. 23. In the cross section of FIG. 24A, the first portion P1 of the dummy sealing layer DSE1 covers the partition 6A. The end portion E1a of the first portion P1 is located in the slit SL. The dummy sealing layer DSE2 covers the partition 6B. For example, the end portion E2b of the dummy sealing layer DSE2 is located in the slit SL and faces the end portion E1a via a gap. In another example, the end portion E2b may be located above the partition 6B. Further, the end portions E1a and E2b overlap.

FIG. 24B is a schematic cross-sectional view of the display device DSP along the B-B line of FIG. 23. The second portion P2 of the dummy sealing layer DSE1 is located above the connecting portion CT. The end portion E2b of the dummy sealing layer DSE2 faces the second portion P2 via a gap. Similarly, the end portion E3a of the dummy sealing layer DSE3 faces the second portion P2 via a gap. In another example, the end portion E2b and the second portion P2 may overlap. Further, the end portion E3a and the second portion P2 may overlap.

FIG. 24C is a schematic cross-sectional view of the display device DSP along the C-C line of FIG. 23. The second portion P2 of the dummy sealing layer DSE1 extends along the slit SL and crosses the connecting portion CT.

In the example of FIG. 24A to FIG. 24C, the respective gaps GP1 are formed between the upper portion 62 of partition 6A and the first portion P1, between the rib layer 5 and the first portion P1 in the slit SL, between the upper portion 62 of the connecting portion CT and the second portion P2, and between the rib layer 5 and the second portion P2 in the slit SL. Further, the respective gaps GP2 are formed between the upper portion 62 of the partition 6B and the dummy sealing layer DSE2 and between the rib layer 5 and the dummy sealing layer DSE2 in the slit SL. Further, the gap GP3 is formed between the upper portion 62 of the partition 6A and the dummy sealing layer DSE3. In another example, the stacked film FL1 may be provided at least a portion of the gap GP1, the stacked film FL2 may be provided at least a portion of the gap GP2, and the stacked film FL3 may be provided at least a portion of the gap GP3.

In FIG. 24A and FIG. 24B, the dummy subpixels DP1, DP2, and DP3 do not have the respective pixel apertures AP1, AP2, and AP3. Thus, the rib layer 5 is interposed between the lower electrode LE1 and the stacked film FL1, between the lower electrode LE2 and the stacked film FL2, and the lower electrode LE3 and the stacked film FL3. In another example, the dummy subpixels DP1, DP2, and DP3 may have the respective pixel apertures AP1, AP2, and AP3.

When the dummy pixel area DMY has the above configuration, the same effects as those in the first embodiment can be achieved in the dummy pixel area DMY as well. When the same configurations as those of the partition 6 and sealing layers SE11, SE12, and SE13 disclosed in the second, third, and fourth embodiments are applied to the partition 6 and the dummy sealing layers DSE1, DSE2, and DSE3 of the dummy pixel area DMY, the same effects as those in these embodiments can be achieved in the dummy pixel area DMY.

In each of the above embodiments, the term “partition” includes various overhanging structures. Even if the overhanging structure has a shape different from the partition disclosed in each embodiment, the portion protruding laterally corresponds to the “upper portion” and the portion recessed below of the portion corresponds to the “lower portion”.

All of the display devices that can be implemented by a person of ordinary skill in the art through arbitrary design changes to the display device disclosed as each embodiment described above come within the scope of the present invention as long as they are in keeping with the spirit of the present invention.

Various types of the modified examples are easily conceivable within the category of the ideas of the present invention by a person of ordinary skill in the art and the modified examples are also considered to fall within the scope of the present invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is

1. A display device, comprising:
a display area including a plurality of subpixels;
a partition surrounding each of the plurality of subpixels and including a lower portion having conductivity and an upper portion having an end portion protruding relative to a side surface of the lower portion;
a plurality of display elements provided in each of the plurality of subpixels and including an organic layer emitting light in response to application of a voltage; and
a plurality of sealing layers each formed of an inorganic insulating material and covering each of the plurality of display elements, wherein the partition includes:
a first segment and a second segment that are divided from each other by a slit extending in a first direction and are arranged in a second direction intersecting the first direction; and
a first connecting portion crossing the slit to connect the first segment with the second segment, and
the plurality of sealing layers include a first sealing layer overlapping at least a portion of the first connecting portion in plan view.

2. The display device of claim 1, wherein
the first sealing layer overlaps at least part of the slit in plan view.

3. The display device of claim 2, wherein
a gap is formed below the first sealing layer in the slit.

4. The display device of claim 1, wherein
the first sealing layer includes:
a first portion overlapping the display element in plan view; and
a second portion extending in the first direction and overlapping at least a portion of the slit in plan view.

5. The display device of claim 4, wherein
the plurality of sealing layers further include a second sealing layer and a third layer that are arranged in the second direction via a slit, and
the second portion extends in the first direction with passing through between the second sealing layer and the third sealing layer.

6. The display device of claim 5, wherein
a gap is formed below the second portion.

7. The display device of claim 1, wherein
an end portion of the first sealing layer in the first direction overlaps the first connecting portion in plan view.

8. The display device of claim 7, wherein
a gap is formed between the first connecting portion and the end portion of the first sealing layer located above the first connecting portion.

9. The display device of claim 7, wherein
the partition further includes a second connecting portion crossing the slit to connect the first segment with the second segment, and
each of both end portions of the first sealing layer in the first direction overlaps the first connecting portion and the second connecting portion in plan view.

10. The display device of claim 1, wherein
an end portion of the first sealing layer in the first direction overlaps the slit in plan view.

11. The display device of claim 10, wherein
a gap is formed below the end portion of the first sealing layer in the slit.

12. The display device of claim 1, wherein
the first sealing layer has a first protrusion portion protruding in a direction parallel to the second direction, and
the first protrusion portion overlaps at least a portion of the first connecting portion in plan view.

13. The display device of claim 12, wherein
a width in the first direction of the first protrusion portion is greater than a width in the first direction of the first connecting portion.

14. The display device of claim 12, wherein
the partition further includes a second connecting portion crossing the slit to connect the first segment with the second segment,
the plurality of sealing layers further include a second sealing layer arranged with the first sealing layer via a slit in the second direction, and
the second sealing layer has a second protrusion portion protruding in a direction parallel to the second direction, and
the second protrusion portion overlaps at least a portion of the second connecting portion in plan view.

15. The display device of claim 14, wherein
a width in the first direction of the second protrusion portion is greater than a width in the first direction of the second connecting portion.

16. The display device of claim 1, further comprising:
a dummy pixel area including a plurality of dummy subpixels and located outside the display area, wherein
a portion of the partition is located in the dummy pixel area and surrounds each of the plurality of dummy pixels.

17. The display device of claim 16, wherein
a portion of the slit is located in the dummy pixel area, and
the partition further includes a third connecting portion connecting the first segment with the second segment in the dummy pixel area.

18. The display device of claim 17, further comprising:
a dummy sealing layer formed of an inorganic insulating material and overlapping one of the plurality of dummy subpixels and at least a portion of the third connecting portion in plan view.

19. The display device of claim 1, wherein
end portions of at least two of the plurality of sealing layers overlap each other in plan view.

20. The display device of claim 1, further comprising:
a resin layer covering the plurality of sealing layers.
